(19) United States
(12) Patent Application Publication
(10) Pub. No.: US 2024/0269903 A1
(43) Pub. Date: Aug. 15, 2024

(54) LIQUID MATERIAL, MOLD, FORMING METHOD, FORMING APPARATUS, IMPRINT APPARATUS, PLANARIZATION APPARATUS, AND ARTICLE MANUFACTURING METHOD

(71) Applicant: CANON KABUSHIKI KAISHA, Tokyo (JP)

(72) Inventors: EIKO ASAMI, Kanagawa (JP); YO WATANABE, Tokyo (JP); NORIYASU HASEGAWA, Tochigi (JP); YUICHI IWASAKI, Tochigi (JP); MASAKI ISHIDA, Tochigi (JP)

(21) Appl. No.: 18/417,242

(22) Filed: Jan. 19, 2024

(30) Foreign Application Priority Data
Feb. 3, 2023 (JP) 2023-015633

(51) Int. Cl. B29C 33/62; B29C 59/00; B29C 59/02

(52) U.S. Cl. CPC B29C 33/62; B29C 59/002; B29C 59/026

(57) ABSTRACT

The present invention provides a liquid material containing a compound having a fluorocarbon chain and a volatile solvent, wherein the compound having the fluorocarbon chain is one of a compound having in a main chain a perfluoro(poly)ether group whose carbon number is 2 to 4, and an acrylic compound having in a side chain a perfluoroalkyl group whose carbon number is 4 to 8.

### BACKGROUND OF THE INVENTION

### Field of the Invention

The present invention relates to a liquid material, a mold, a forming method, a forming apparatus, an imprint apparatus, a planarization apparatus, and an article manufacturing method.

### Description of the Related Art

As a method of forming a fine pattern (structure having concave and convex portions) in the nanoscale (for example, 1 nm (inclusive) to 1,000 nm (inclusive)), a UV nanoimprint technology has attracted attention. According to the UV nanoimprint technology, an imprint mold that bears a pattern having concave and convex portions and is transparent to light (for example, ultraviolet light) is brought into contact with a curable composition (resist) supplied on a substrate. After the curable composition is cured to form a cured film, the mold is separated from the cured film, forming a pattern on the cured film on the substrate. Then, the substrate is processed using the pattern of the cured film as a mask, thus forming a fine pattern on the substrate. In the UV nanoimprint technology, the processing (that is, imprint processing) of forming a cured film pattern is repeated for respective positions (shot regions) on the substrate.

A mold used in the UV nanoimprint technology is generally formed by processing silica glass. More specifically, the mold can be fabricated by forming a convex mesa portion on silica glass, and forming a fine pattern having concave and convex portions on the end face of the mesa portion serving as a contact surface (imprint surface) that comes into contact with a curable composition on a substrate. The pattern having concave and convex portions is pressed against a curable composition on a substrate. When the end face of the mesa portion of the mold is pressed against the curable composition on the substrate, the curable composition is still fluid, sometimes runs off from the end face (contact surface) of the mesa portion, and runs up along the side surface of the mesa portion. This phenomenon is sometimes called “extrusion”. After the curable composition on the substrate is cured, the mold is separated from the cured film of the curable composition, but the curable composition running up along the side surface of the mesa portion may remain attached to the side surface. As the imprint processing of pressing the mold against the curable composition is repeated, the amount of the curable composition attached to the side surface of the mesa portion gradually increases, and the curable composition may fall onto the substrate at an unintended timing and cause a serious defect on the substrate. Japanese Patent Nos. 6529843 and 3601062 propose techniques of preventing attachment of a curable composition to the side wall of an imprint mold.

Japanese Patent No. 6529843 discloses a technique of forming a liquid repellent layer at a mesa side wall portion by applying, to the mesa side wall portion, a liquid repellent material formed from a liquid repellent component, a non liquid-repellent component, and a volatile solvent that dissolves the liquid repellent component, so that the mesa side wall portion becomes liquid repellent with respect to a curable composition. However, the initial liquid repellency of the liquid repellent layer disclosed in Japanese Patent No. 6529843 is not sufficiently high because, for example, the contact angle with respect to the curable composition is 65°. In this case, repetitive imprint processing degrades the liquid repellency owing to extrusion of the curable composition and exposure for curing the curable composition. Thus, attachment of the curable composition to the side wall of the mesa portion cannot be satisfactorily prevented. Japanese Patent No. 3601062 discloses a technique in which a surface treatment agent containing a polyfluoroalkyl group exhibits water and oil repellency, but neither discloses its concrete example nor clearly indicates an application method to an imprint mold.

### SUMMARY OF THE INVENTION

The present invention provides, for example, a new material for forming a liquid repellent layer with respect to a curable composition on part of a mold that molds the curable composition.

According to one aspect of the present invention, there is provided a liquid material containing a compound having a fluorocarbon chain and a volatile solvent, wherein the compound having the fluorocarbon chain is one of a compound having in a main chain a perfluoro(poly)ether group whose carbon number is 2 to 4, and an acrylic compound having in a side chain a perfluoroalkyl group whose carbon number is 4 to 8.

Further features of the present invention will become apparent from the following description of exemplary embodiments with reference to the attached drawings.

### BRIEF DESCRIPTION OF THE DRAWINGS

FIG. 1 is a schematic view showing an example of the structure of a mold;

FIGS. 2A-2D is a view showing examples of an acrylic compound having in a side chain a perfluoroalkyl group whose carbon number is 4 to 8;

FIG. 3 is a schematic view showing an example of the arrangement of a layer forming apparatus;

FIG. 4 is a view for explaining an example of a supply method of supplying a liquid repellent material to part of a mold;

FIG. 5 is a schematic view showing an example of the arrangement of an imprint apparatus;

FIG. 6 is a view for explaining imprint processing;

FIG. 7 is a view showing a model used to calculate the relationship between the contact angle and the extrusion height;

FIG. 8 is a graph showing the result of calculating the relationship between the contact angle and the extrusion height; and

FIG. 9 is a view (table) showing Examples 1 to 6 according to the present invention.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made an invention that requires all such features, and multiple such features may be combined as appropriate. Furthermore, in the attached drawings, the same reference numerals are given to the same or similar configurations, and redundant description thereof is omitted.

In the specification and the accompanying drawings, directions will be indicated on an XYZ coordinate system in which directions parallel to the contact surface of a mold are defined as the X-Y plane, unless otherwise specified. Directions parallel to the X-, Y-, and Z-axes of the XYZ coordinate system are the X, Y, and Z directions, respectively. A rotation about the X-axis, a rotation about the Y-axis, and a rotation about the Z-axis are θX, θY, and θZ, respectively. Control or driving concerning the X-axis, the Y-axis, and the Z-axis means control or driving concerning a direction parallel to the X-axis, a direction parallel to the Y-axis, and a direction parallel to the Z-axis, respectively. In addition, control or driving concerning the θX-axis, the θY-axis, and the θZ-axis means control or driving concerning a rotation about an axis parallel to the X-axis, a rotation about an axis parallel to the Y-axis, and a rotation about an axis parallel to the Z-axis, respectively. In addition, a position is information that can be specified based on coordinates on the X-, Y-, and Z-axes, and an orientation is information that can be specified by values on the θX-, θY-, and θZ-axes. Note that the contact surface of a mold is a surface that comes into contact with a curable composition on a substrate, and can be the end face of a convex portion (mesa portion) formed on the mold. The contact surface of the mold may be understood as a surface (imprint surface) that is pressed against the curable composition on the substrate.

### <Mold>

First, a mold 10 according to an embodiment of the present invention will be described. The mold 10 is used for molding processing to mold a curable composition on a substrate. In the molding processing, the mold 10 is pressed against a curable composition on a substrate to mold the curable composition. Examples of the molding processing are imprint processing and planarization processing. In the imprint processing, the mold 10 bearing a pattern having concave and convex portions is brought into contact with a curable composition (imprint material) on a substrate to form (transfer) the pattern on the curable composition. In the planarization processing, the mold 10 having a flat surface is brought into contact with a curable composition on a substrate to planarize the surface of the curable composition. The imprint processing will be exemplified below unless otherwise specified.

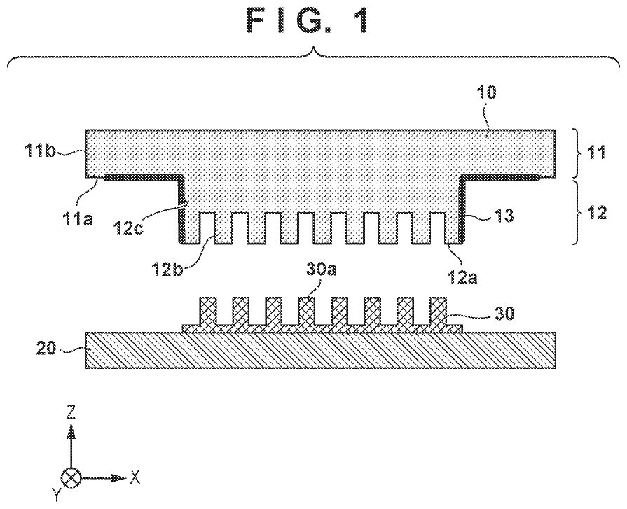

FIG. 1 is a schematic view (sectional view) showing an example of the structure of the mold 10 according to the embodiment of the present invention. FIG. 1 also shows a pattern 30a of the cured film (to be also referred to as a cured film pattern 30a hereinafter) of a curable composition 30 formed on a substrate 20 through imprint processing using the mold 10. The substrate 20 is a processing target substrate such as a wafer.

The mold 10 shown in FIG. 1 is used in imprint processing (nanoimprint). The mold 10 is formed into a shape in which the contact surface of the mold 10 projects so that even when the contact surface (imprint surface) of the mold 10 is not parallel to the surface of the substrate 20, a portion of the mold 10 other than the contact surface does not contact the substrate 20. More specifically, the mold 10 includes a base portion 11 (base body) having a major surface 11a, and a mesa portion 12 (convex portion) projecting from the major surface 11a. An end face 12a of the mesa portion 12 in the mold 10 functions as a contact surface (that is, an imprint surface that is pressed against the curable composition 30 on the substrate 20) that comes into contact with the curable composition 30 on the substrate 20. When the mold 10 is used in imprint processing, a pattern 12b having concave and convex portions that is transferred to a curable composition on the substrate 20 is provided on the end face 12a of the mesa portion 12 in the mold 10. When the mold 10 is used in planarization processing, the end face 12a of the mesa portion 12 in the mold 10 is configured as a flat surface for planarizing a curable composition on the substrate 20. This structure ensures a predetermined clearance between a portion of the mold 10 other than the mesa portion 12 and the substrate 20 in imprint processing or planarization processing so as to avoid direct contact between the mold 10 and the substrate 20.

In imprint processing, the mold 10 bearing the fine pattern 12b having concave and convex portions on the end face 12a (contact surface) of the mesa portion 12 is pressed against the curable composition 30 on the substrate 20. Then, the pattern 12b of the mold 10 is transferred to the curable composition 30 on the substrate 20, forming the cured film pattern 30a of the curable composition 30 on the substrate 20. When the mold 10 (mesa portion 12) is pressed against the curable composition 30 on the substrate 20, the curable composition 30 sometimes runs off from the mesa portion 12 and runs up along a side surface 12c of the mesa portion 12 (this phenomenon will be sometimes referred to as “extrusion”). In this case, the curable composition 30 is attached to the side surface 12c of the mesa portion 12 of the mold 10. After the curable composition 30 on the substrate 20 is cured, the mold 10 is separated from the cured film of the curable composition 30, but the curable composition 30 running up along the side surface 12c of the mesa portion 12 remains attached to the side surface 12c. As imprint processing is repeated, the amount of the curable composition 30 attached to the side surface 12c of the mesa portion 12 of the mold 10 gradually increases, and the curable composition 30 may fall onto the substrate 20 at an unintended timing and cause a serious defect on the substrate 20.

Therefore, in the mold 10 according to the embodiment, a liquid repellent layer 13 is formed on at least part of the side surface 12c of the mesa portion 12 in order to prevent attachment of the curable composition 30 to the side surface 12c of the mesa portion 12 of the mold 10 when the mold 10 is pressed against the curable composition 30. The liquid repellent layer 13 is a layer (film) having liquid repellency with respect to an organic substance, and is constituted as a layer higher in liquid repellency with respect to the curable composition 30 than the surface material (for example, silica glass) of the mold 10. The liquid repellent layer 13 is preferably formed at least at a portion (that is, a portion on the end face 12a side) of the side surface 12c of the mesa portion 12 that is connected to the end face 12a (contact surface), and may be formed on the entire side surface 12c of the mesa portion 12. FIG. 1 shows an example in which the liquid repellent layer 13 is provided continuously on the entire side surface 12c of the mesa portion 12 and part of the major surface 11a of the base portion 11 in the mold 10.

The liquid repellent layer 13 may be provided on at least part of the major surface 11a of the base portion 11, or further may be provided on at least part of a side surface 11b of the base portion 11. More specifically, the base portion 11 of the mold 10 includes the first surface (major surface 11a) that is connected to the side surface 12c of the mesa portion 12 and extends from the side surface 12c in a crossing direction, and the second surface (side surface 11b) that is connected to the first surface and extends from the first surface in a crossing direction. The liquid repellent layer 13 may be formed on both the first surface (major surface 11a) and second surface (side surface 11b) of the base portion 11 in the mold 10. In this manner, the liquid repellent layer 13 may be formed not only on the side surface 12c of the mesa portion 12 in the mold 10, but also on at least part of the major surface 11a and/or side surface 11b of the base portion 11.

When forming the liquid repellent layer 13 on the surface (particularly the side surface 12c of the mesa portion 12) of the mold 10, it is necessary not to form the liquid repellent layer 13 on the end face 12a (contact surface) of the mesa portion 12. If the liquid repellent layer 13 is formed on the end face 12a of the mesa portion 12, an unfilled defect may be generated in the pattern of a curable composition (cured film) formed on the substrate 20 through imprint processing. Note that it is sometimes permitted to provide the liquid repellent layer 13 at the peripheral portion (for example, in a range of several m to several mm from the periphery) of the end face 12a of the mesa portion 12.

### <Material of Liquid Repellent Layer>

Next, the material of the liquid repellent layer 13 according to the embodiment of the present invention will be described. The material of the liquid repellent layer 13 is a liquid material (to be also referred to as a liquid repellent material hereinafter) containing a compound having a fluorocarbon chain and a volatile solvent that dissolves the compound. The liquid repellent layer 13 is formed on part of the mold 10 through a supply step of supplying the liquid repellent material to part (for example, at least part of the side surface 12c of the mesa portion 12) of the mold 10, and a volatilization step of volatilizing the volatile solvent contained in the liquid repellent material after the supply step. The liquid repellent material containing a compound having a fluorocarbon chain can be used to form on part of the mold 10 the preferable liquid repellent layer 13 high in liquid repellency with respect to the curable composition 30. An index representing the liquid repellency of the liquid repellent layer 13 is, for example, the contact angle of a droplet (to be also referred to as a contact angle hereinafter) when the curable composition 30 is dropped as a droplet onto a liquid repellent layer.

The “compound having a fluorocarbon chain” contained in the liquid repellent material (liquid material) is a compound having a perfluoro(poly)ether group in a main chain, or an acrylic compound having a perfluoroalkyl group in a side chain. The carbon number of the perfluoro(poly)ether group is 2 to 4, and that of the perfluoroalkyl group is 4 to 8. The compound having a fluorocarbon chain may have a functional group in accordance with the purpose. Examples of the functional group are a hydroxy group, a formyl group, a carboxyl group, a carbonyl group, an amino group, and an alkoxysilyl group.

The compound having in a main chain a perfluoro(poly)ether group whose carbon number is 2 to 4 may be a polymer or an oligomer. Examples of the compound are structures below:

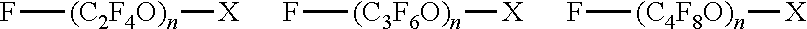

where “n” is an integer in the range of 1 to 1000 and is more preferably an integer in the range of 1 to 15, and “X” is one of OH, SiOH, and Si(OCH₃)₃.

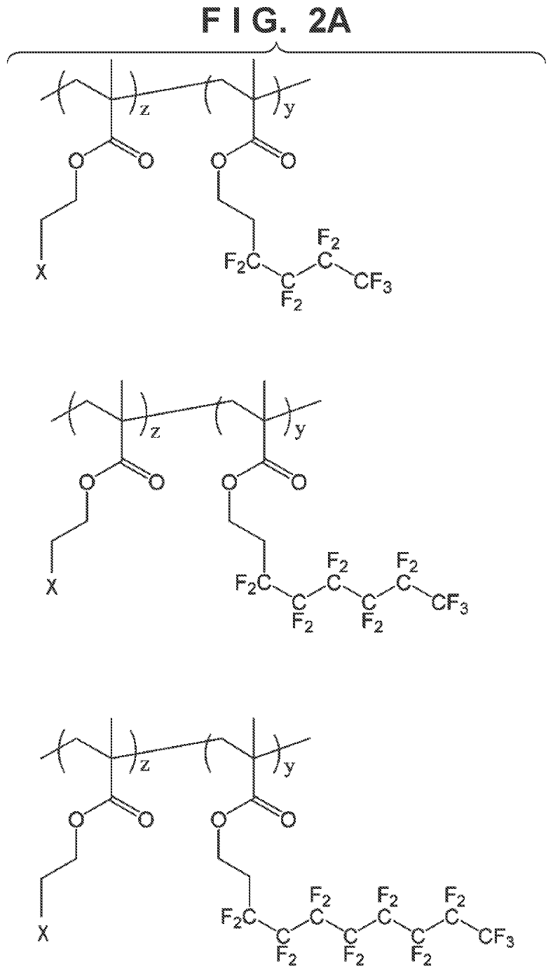

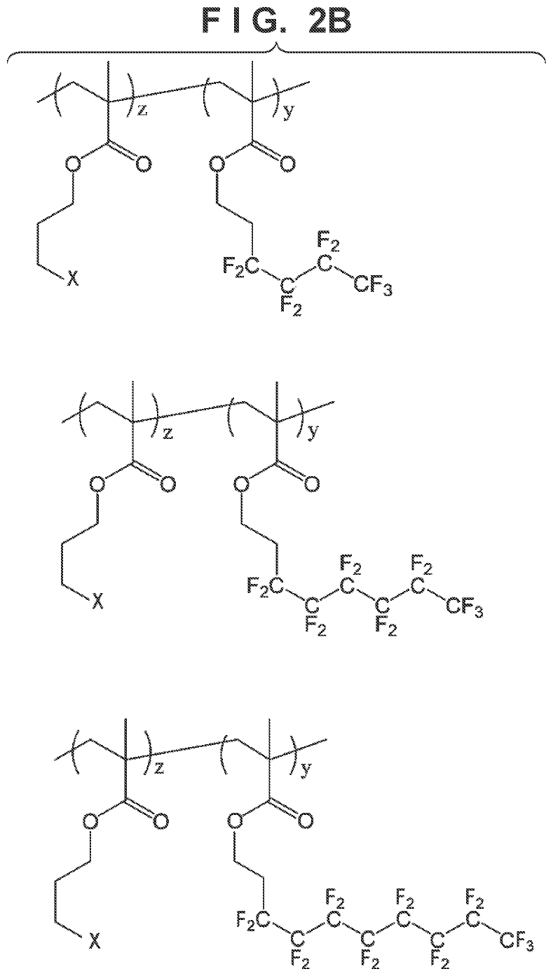

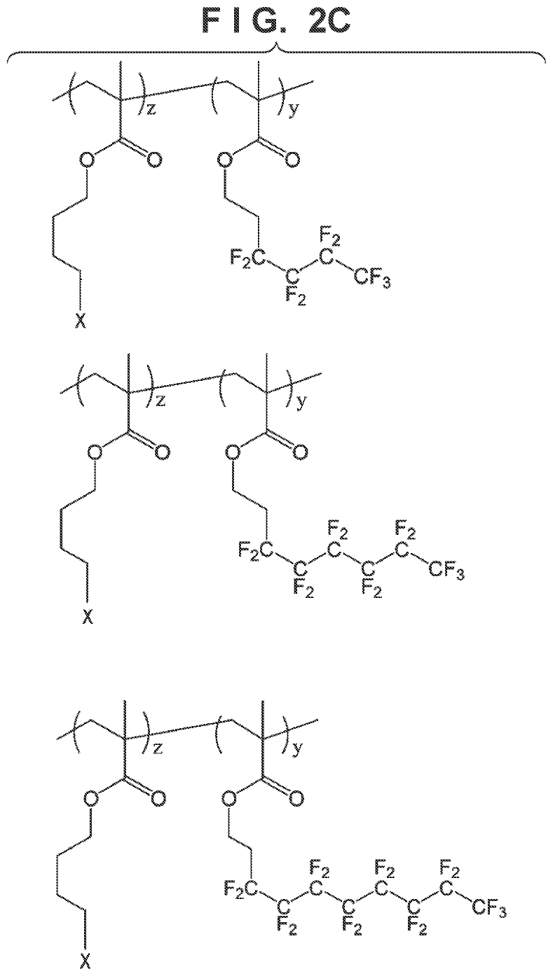

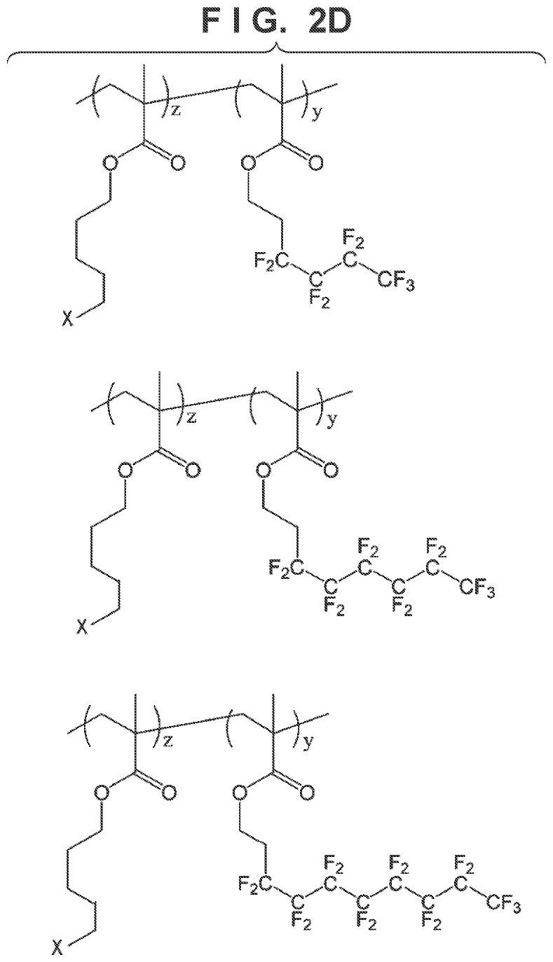

The acrylic compound having in a side chain a perfluoroalkyl group whose carbon number is 4 to 8 may be a polymer or an oligomer. Examples of the acrylic compound are structures shown in FIGS. 2A-2D. “y” and “z” are integers in the range of 2 to 1000, “y” is more preferably an integer in the range of 2 to 100, and “z” is more preferably an integer in the range of 0 to 30. “X” is one of H, OH, SiOH, and Si(OCH₃)₃.

The volatile solvent is not particularly limited as long as it dissolves a compound having a fluorocarbon chain. When forming the liquid repellent layer 13 on part of the mold 10, the volatile solvent volatizes (vaporizes). To shorten the time of volatization of the volatile solvent, the boiling point of the volatile solvent is desirably low. However, if the boiling point of the volatile solvent is excessively low, the compound having a fluorocarbon chain is solidified at the distal end of a supply head 42 of a layer forming apparatus 40 (to be described later), and it may be difficult to stably supply the liquid repellent material to part of the mold 10. Thus, the boiling point of the volatile solvent is preferably 50° C. to 140° C., and more preferably 60° C. to 100° C.

The solid concentration of the compound having a fluorocarbon chain with respect to the entire liquid repellent material (liquid material) preferably falls within the range of 0.008 wt % to 0.09 wt %. If the solid concentration is lower than 0.008 wt %, the liquid repellent layer 13 having liquid repellency necessary to prevent attachment of the curable composition 30 cannot be formed. If the solid concentration is higher than 0.09 wt %, the liquid repellent layer 13 readily peels off from the mold 10 after the liquid repellent layer 13 is formed. The solid concentration is more preferably 0.01 wt % to 0.09 wt %, and further preferably 0.02 wt % to 0.07 wt %.

The liquid repellent layer 13 formed on part of the mold 10 through the above-described supply and volatilization steps is in a state in which the volatile solvent has volatized. That is, it may be understood that the liquid repellent layer 13 contains a compound having in a main chain a perfluoro(poly)ether group whose carbon number is 2 to 4, or an acrylic compound having in a side chain a perfluoroalkyl group whose carbon number is 4 to 8, and does not contain the volatile solvent. The liquid repellent layer 13 formed on part of the mold 10 has a characteristic in which the contact angle serving as an index representing liquid repellency is 70° (inclusive) to less than 100°.

### <Layer Forming Apparatus>

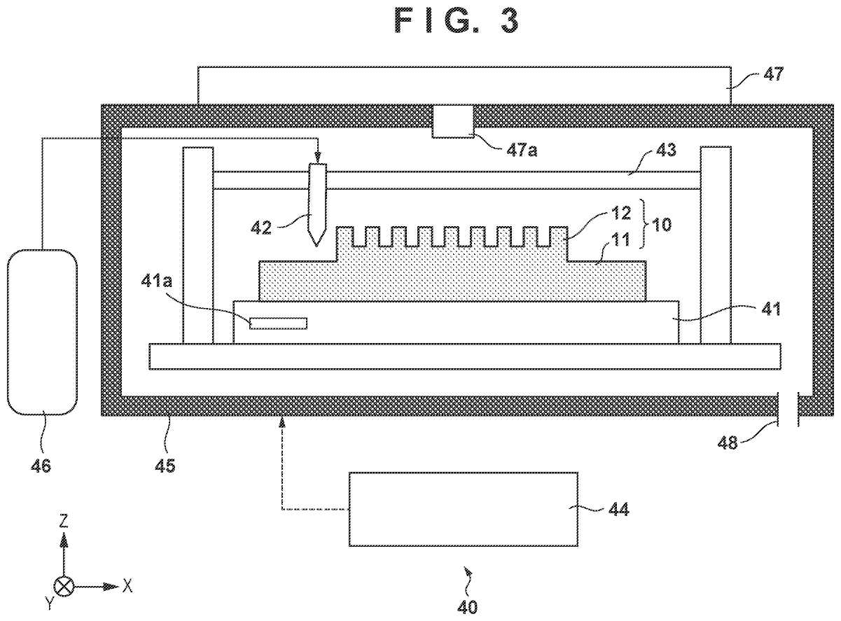

Next, the layer forming apparatus 40 according to the embodiment of the present invention will be described. The layer forming apparatus 40 is an apparatus that forms the liquid repellent layer 13 on part of the mold 10 and may be understood as a liquid repelling apparatus that makes part of the mold 10 liquid repellent. FIG. 3 is a schematic view showing an example of the arrangement of the layer forming apparatus 40 according to the embodiment. The layer forming apparatus 40 can include a stage 41 that holds the mold 10, the supply head 42 (supply unit) that supplies a liquid repellent material to part of the mold 10, a moving mechanism 43 that moves the supply head 42, and a controller 44. The stage 41, the supply head 42, and the moving mechanism 43 are arranged in a processing chamber 45 (chamber), and supply processing (supply step) of supplying a liquid repellent material to part of the mold 10 is performed in the processing chamber 45. Part of the mold 10 includes at least part of the side surface 12c of the mesa portion 12 of the mold 10.

The stage 41 holds the mold 10 by a vacuum suction force or the like. In the embodiment, the position of the stage 41 in the processing chamber 45 is fixed, but the stage 41 may be configured to be movable in the processing chamber 45. That is, the stage 41 may be configured to move the mold 10 relatively in the X, Y, and Z directions with respect to the supply head 42.

The supply head 42 is a dispenser that discharges a liquid repellent material in liquid form toward the mold 10 held by the stage 41. The liquid repellent material is retained (stored) in a tank 46 arranged outside the processing chamber 45, and supplied from the tank 46 to the supply head 42. The supply head 42 discharges the liquid repellent material at a predetermined timing under the control of the controller 44.

The moving mechanism 43 supports the supply head 42 and relatively moves the supply head 42 with respect to the stage 41. The moving mechanism 43 can be configured to include mechanisms that move the supply head 42 in the X, Y, and Z directions, respectively, and operate independently. As the moving mechanism 43, various moving mechanisms can be used including a linear motor moving mechanism, an air stage moving mechanism, and a feed screw moving mechanism.

The controller 44 is formed from, for example, a computer including a processor such as a Central Processing Unit (CPU) and a storage such as a memory. The controller 44 comprehensively controls the respective units of the layer forming apparatus 40 in accordance with various programs stored in the storage. Various programs include a program for controlling supply processing, and in addition may include a program for controlling processing of conveying the mold 10 onto the stage 41 by a conveyance mechanism (not shown).

The controller 44 according to the embodiment controls the respective units of the layer forming apparatus 40 to control supply processing of supplying a liquid repellent material to part of the mold 10. More specifically, the controller 44 controls supply processing of supplying a liquid repellent material to part of the mold 10 by discharging the liquid repellent material from the supply head 42 at a predetermined timing while relatively moving the supply head 42 and the mold 10. In the embodiment, the relative movement of the supply head 42 and mold 10 in supply processing is performed by moving the supply head 42 by the moving mechanism 43, but is not limited to this. For example, when the stage 41 holding the mold 10 is configured to be movable in the X and Y directions, the relative movement of the supply head 42 and mold 10 in supply processing may be performed by moving the mold 10 by the stage 41. Alternatively, the relative movement may be performed by relatively moving the mold 10 and the supply head 42 by the stage 41 and the moving mechanism 43.

The processing chamber 45 is formed into a box shape so that it can contain the stage 41, the supply head 42, the moving mechanism 43, and the like. A cleaning mechanism 47 (filter device) is provided at the upper portion of the processing chamber 45 to supply into the processing chamber 45 clean air via a filter 47a configured to remove a foreign substance contained in air. An exhaust port 48 is provided at the lower portion (bottom surface) of the processing chamber 45. Clean air flows from the filter 47a of the cleaning mechanism 47 toward the exhaust port 48 in the processing chamber 45 to keep the inside of the processing chamber 45 clean by a downflow (vertical laminar flow). The filter 47a can be, for example, a ULPA filter or a HEPA filter.

The layer forming apparatus 40 may be configured to perform volatilization processing (volatilization step) of volatizing the volatile solvent of a liquid repellent material supplied to part of the mold 10. The volatilization processing can be performed by keeping waiting the mold 10 to which the liquid repellent material is supplied. To do this, a waiting position for keeping waiting the mold 10 to which the liquid repellent material is supplied may be provided in the layer forming apparatus 40. The waiting position may be on the stage 41 or a stocker for stocking the mold 10 to which the liquid repellent material is supplied. When a position on the stage 41 is used as the waiting position, a temperature control mechanism 41a may be provided on the stage 41 to shorten the time necessary for volatilization processing. In this case, volatilization of the volatile solvent of the liquid repellent material supplied to the mold 10 can be promoted by raising the temperature of the mold 10 by the temperature control mechanism 41a of the stage 41.

A conveyance mechanism of conveying the mold 10, a loading unit, an unloading unit, and the like can also be attached to the layer forming apparatus 40. Further, the layer forming apparatus 40 may be arranged in a cleaning apparatus that cleans the mold 10, or a molding apparatus that performs molding processing (imprint processing or planarization processing). A function of forming the liquid repellent layer 13 on part of the mold 10 can be added to the cleaning apparatus or the molding apparatus.

### <Method of Forming Liquid Repellent Layer>

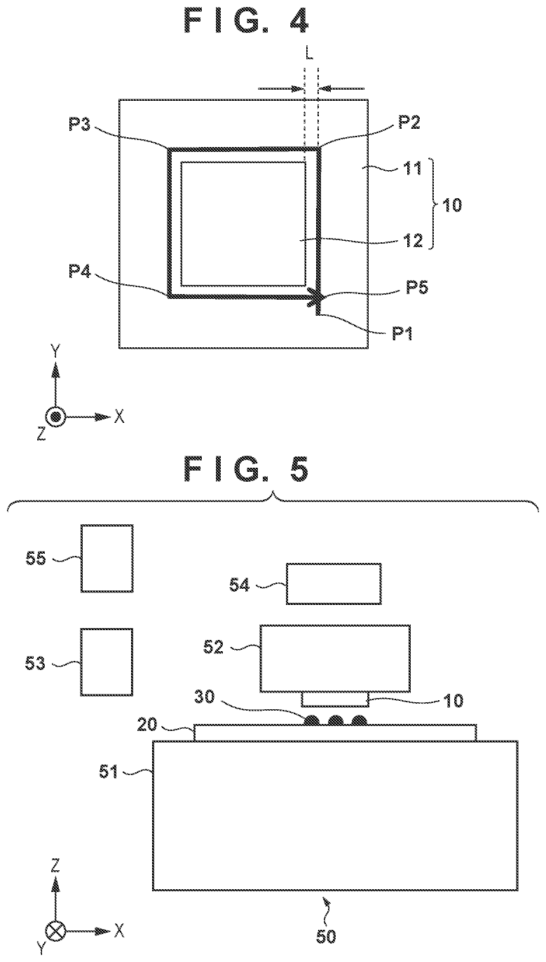

Next, details of a method of forming the liquid repellent layer 13 on part of the mold 10 by the layer forming apparatus 40 will be described. FIG. 4 is a view for explaining an example of a supply method of supplying a liquid repellent material to part of the mold 10. FIG. 4 is a view when the mold 10 held by the stage 41 in the layer forming apparatus 40 shown in FIG. 3 is viewed from the top (+Z direction).

The controller 44 controls the moving mechanism 43 to move the supply head 42 along supply paths (coating paths) P1 to P5 on the major surface 11a of the base portion 11 of the mold 10 in a state in which the supply head 42 is maintained at a predetermined height. The controller 44 controls the supply head 42 to continuously discharge a liquid repellent material in liquid form onto the major surface 11a of the base portion 11 of the mold 10 while moving the supply head 42 along the supply paths P1 to P5.

The supply paths P1 to P5 are paths for moving the supply head 42 in order at positions P1, P2, P3, P4, and P5 on the major surface 11a of the base portion 11 along the periphery of the mesa portion 12. The supply paths P1 to P5 are set apart from the mesa portion 12 (end face 12a) by a predetermined distance L (for example, 1 mm) so as to supply the liquid repellent material discharged from the supply head 42 even to the side surface of the mesa portion 12. P1 is the discharge start position of the liquid repellent material, and P5 is the discharge stop position of the liquid repellent material. A region where the liquid repellent material is supplied along the coating paths P1 to P5 has, for example, a frame shape surrounding the mesa portion 12.

The liquid repellent material in liquid form supplied onto the major surface 11a of the base portion 11 along the coating paths P1 to P5 spreads owing to wettability and reaches the side surface 12c of the mesa portion 12. The spread liquid repellent material in liquid form stays on the side surface 12c and attaches to it without reaching the end face 12a over the side surface 12c of the mesa portion 12. A volatile solvent contained in the liquid repellent material in liquid form volatizes, and the liquid repellent material dries, thereby forming, on at least part of the side surface 12c of the mesa portion 12, the liquid repellent layer 13 containing a compound having a fluorocarbon chain as a liquid repellent component. At this time, no liquid repellent layer is formed on the end face 12a of the mesa portion 12 functioning as a contact surface (imprint surface).

Note that the supply paths P1 to P5 used in the above description are an example, and suffice to be paths surrounding the mesa portion 12 (end face 12a) so that the liquid repellent material in liquid form can be supplied to at least part of the side surface 12c of the mesa portion 12. Also, the discharge start position and discharge stop position of the liquid repellent material are arbitrary, and the liquid repellent material may not be continuously supplied (coated) on the supply paths. When the liquid repellent material are not continuously supplied on the supply paths, supply of the liquid repellent material is so devised as not to generate an unsupplied portion on the supply paths. Further, a protection film for protecting the end face 12a not to supply (attach) the liquid repellent material to the end face 12a of the mesa portion 12 may be formed on the end face 12a.

### <Imprint Apparatus>

Next, an imprint apparatus 50 according to the embodiment of the present invention will be described. FIG. 5 is a schematic view showing an example of the arrangement of the imprint apparatus 50 according to the embodiment. The imprint apparatus 50 is a lithography apparatus adopted in the manufacturing process (lithography process) of a semiconductor device, a magnetic storage medium, a liquid crystal display device, or the like. The imprint apparatus 50 performs imprint processing of bringing the mold 10 and the curable composition 30 on the substrate 20 into contact with each other, applying curing energy to the curable composition 30, and forming on the substrate 20 the pattern of the cured film to which the pattern of the mold 10 having concave and convex portions is transferred. The imprint apparatus 50 according to the embodiment uses the mold 10 on which a pattern having concave and convex portions is provided on the end face 12a (contact surface or imprint surface) of the mesa portion 12, and the liquid repellent layer 13 is formed on at least part of the side surface 12c of the mesa portion 12 in the mold 10. Note that the arrangement of the imprint apparatus 50 shown in FIG. 1 is applicable to even a planarization apparatus that performs planarization processing. The planarization apparatus uses a mold in which the end face of the mesa portion is constituted as a flat surface. Even in the mold used in the planarization apparatus, a liquid repellent layer can be formed on at least part of the side surface of the mesa portion.

The imprint apparatus 50 can include a substrate stage 51, an imprint head 52, a supply unit 53, a curing unit 54, and a controller 55. The substrate stage 51 is constituted to hold the substrate 20 by vacuum suction force or the like and be movable in the X and Y directions, and can be used to align the mold 10 and the substrate 20. The imprint head 52 (mold holder) holds the mold 10 by a vacuum suction force or the like. The imprint head 52 moves the mold 10 in the Z direction so as to perform processing of bringing (imprinting) the mold 10 into contact with the curable composition 30 on the substrate 20, and processing of separating the mold 10 from the curable composition 30 (cured film) on the substrate 20. The supply unit 53 (dispenser) supplies (arranges) the curable composition 30 on the substrate 20 by discretely discharging the curable composition 30 as a plurality of droplets toward the substrate 20. The curing unit 54 (light irradiating unit) cures the curable composition 30 by irradiating the curable composition 30 with light (for example, ultraviolet light) via the mold 10 in a state in which the mold 10 and the curable composition 30 on the substrate 20 contact each other.

The controller 55 is formed from, for example, a computer including a processor such as a Central Processing Unit (CPU) and a storage such as a memory. The controller 55 comprehensively controls the respective units of the imprint apparatus 50 in accordance with programs stored in the storage. The controller 55 controls imprint processing of transferring the pattern of the mold 10 having concave and convex portions to the curable composition 30 on the substrate 20 by controlling the operations, adjustments, and the like of the respective units of the imprint apparatus 50. The layer forming apparatus 40 may be provided in the imprint apparatus 50. In this case, the mold 10 on which the liquid repellent layer 13 is formed by the layer forming apparatus 40 can be conveyed to the imprint head 52 by a conveyance mechanism (not shown). The controller 44 of the layer forming apparatus 40 may be constituted as part of the controller 55 of the imprint apparatus 50. The layer forming apparatus 40 may also be provided in a planarization apparatus having an arrangement similar to that of the imprint apparatus 50.

### <Imprint Processing>

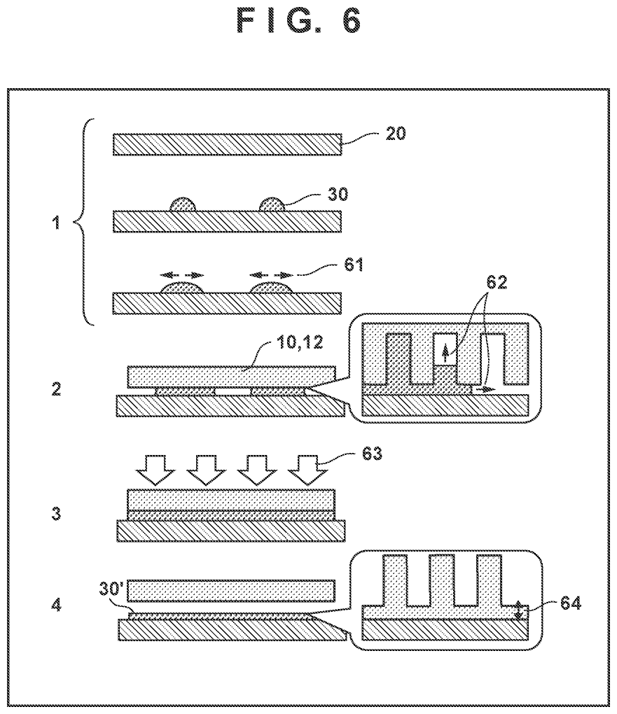

Next, imprint processing (imprint method) according to the embodiment of the present invention will be described. FIG. 6 is a view for explaining imprint processing performed by the imprint apparatus 50. FIG. 6 shows the mold 10 (mesa portion 12), the substrate 20, and the curable composition 30, and an illustration of the remaining members and units is omitted.

The cured film (cured material) of the curable composition obtained on the substrate 20 by imprint processing according to the embodiment is preferably a film having a pattern at a size of 1 nm (inclusive) to 10 mm (inclusive). Note that a pattern forming technique of fabricating a film having a pattern (structure having concave and convex portions) in the nanoscale (1 nm (inclusive) to 1,000 nm (inclusive)) using light is generally called a UV nanoimprint method. Imprint processing according to the embodiment uses the UV nanoimprint method.

Respective steps in imprint processing according to the embodiment will be explained below.

### (Arrangement Step)

Frist, an arrangement step of arranging the liquid curable composition 30 on the substrate 20 is performed. As an example of the arrangement step, as schematically shown in [1] of FIG. 6, the curable composition 30 (resist) is discretely dropped and arranged as a plurality of droplets onto the substrate 20. As a method of arranging droplets of the curable composition, an inkjet method is particularly preferably used. Droplets of the curable composition 30 can be arranged densely in a region on the substrate 20 facing a portion where concave portions of the pattern having concave and convex portions out of the end face 12a of the mesa portion 12 in the mold 10 exist densely, and can be arranged coarsely in a region on the substrate 20 facing a portion where concave portions exist coarsely. Accordingly, a residual film (to be described later) can be controlled to have a uniform thickness regardless of the density of concave portions in the pattern of the mold 10 having concave and convex portions. The dropped droplets of the curable composition 30 spreads gradually over time on the surface of the substrate 20. Arrows 61 indicate directions in which the droplets of the curable composition 30 spread. Another example of the arrangement step is a method of arranging the curable composition 30 on the substrate 20 using spin coating. In this case, the curable composition 30 is continuously arranged on the substrate 20.

The viscosity of a mixture of components of the curable composition 30 except the solvent at 25° C. in the embodiment is preferably 1 mPa-s (inclusive) to less than 40 mPa-s, and more preferably 1 mPa-s (inclusive) to less than 20 mPa-s. If the viscosity of the curable composition 30 exceeds 40 mPa-s, coating cannot be performed by the inkjet method of discretely arranging droplets in accordance with the density of a desired pattern to uniform the thickness of the residual film and form a high-precision pattern. If the viscosity is lower than 1 mPa-s, the curable composition immediately after coating (arrangement) on the substrate may undesirably flow to generate coating unevenness, or the curable composition 30 may undesirably run off (flow out) from the end portion of the mold 10 in a contact step (to be described later).

The surface tension of the curable composition 30° C. at 23° C. in the embodiment is preferably 5 mN/m (inclusive) to 70 mN/m (inclusive) as for a compound of components except the solvent, more preferably 7 mN/m (inclusive) to 50 mN/m (inclusive), and further preferably 10 mN/m (inclusive) to 40 mN/m (inclusive). As the surface tension is higher such as 5 mN/m or more, the capillary force acts more strongly. When the mold 10 is brought into contact with the curable composition 30, filling (spread and fill) of the concave portions of the pattern of the mold 10 having concave and convex portions with the curable composition 30 can be completed in a short time. If the surface tension is set to be 70 mN/m or less, the surface smoothness of a cured film obtained by curing the curable composition 30 can be improved.

The contact angle of the curable composition 30 with respect to the contact surface (end face 12a) of the mold 10 and the surface of the substrate 20 in the embodiment is preferably 0° (inclusive) to 100° (inclusive) as for a compound of components except the solvent. If the contact angle is larger than 100°, the capillary force acts in a negative direction (direction in which the contact interface between the mold 10 and the curable composition 30 contracts) at the concave portions of the pattern of the mold 10 having concave and convex portions and a gap between the mold 10 and the substrate 20, failing to obtain filling with the curable composition 30. The contact angle is particularly preferably 0° (inclusive) to 30° (inclusive). As the contact angle is smaller, the capillary force acts more strongly, increasing the filling speed of the curable composition 30.

The substrate 20 serving as a target on which the curable composition 30 is arranged is a processing target substrate, and a silicon wafer is generally used. A processing target layer may be formed on the substrate 20. Still another layer may be formed between the substrate 20 and the processing target layer. When a quartz substrate (for example, a blank mold formed from quartz) is used as the substrate 20, a replica (replica mold) of the mold 10 can be fabricated. However, the substrate 20 is not limited to the silicon wafer or the quartz substrate. The substrate 20 can be arbitrarily selected from the group known as substrates for semiconductor devices, consisting of aluminum, a titanium-tungsten alloy, an aluminum-silicon alloy, an aluminum-copper-silicon alloy, silicon oxide, and silicon nitride. To improve adhesion to the curable composition 30, the surface of the substrate 20 (processing target substrate) or the processing target layer may undergo surface treatment such as silane coupling treatment, silazane treatment, or film formation of an organic thin film.

### (Contact Step)

After that, a contact step of bringing the mold 10 (end face 12a (contact surface) of the mesa portion 12) into contact with the liquid curable composition 30 arranged on the substrate 20 is performed. In the contact step, as schematically shown in [2] of FIG. 6, the mold 10 bearing a pattern (prototype pattern) having concave and convex portions that is transferred to the curable composition 30 on the substrate 20 is brought into contact with the curable composition 30 arranged on the substrate 20 in the above-described arrangement step. As a result, the concave portions of the fine pattern having concave and convex portions provided on the mold 10 are filled (fill) with the curable composition 30. The curable composition 30 spreads between the mold 10 and the substrate 20, forming the liquid film of the curable composition 30 between the mold 10 and the substrate 20. Arrows 62 indicate directions in which the curable composition 30 proceeds (a direction in which the concave portions of the mold 10 are filled with the curable composition 30, and a direction in which the curable composition 30 spreads between the mold 10 and the substrate 20).

Considering a curing step (to be described later), the mold 10 can be formed from a light-transmitting material. Examples of the quality of the material (base material) of the mold 10 are preferably an optically transparent resin such as glass, quartz, PMMA, and a polycarbonate resin, a flexible film such as a transparent metallized film or polydimethylsiloxane, a photo-curing film, and a metal film. When the optically transparent resin is used as the quality of the material of the mold 10, a resin that is not dissolved by a component contained in the curable composition 30 needs to be selected. The quality of the material of the mold 10 is especially preferably quartz because of a small thermal expansion coefficient and a small pattern distortion. Note that PMMA stands for Poly Methyl Methacrylate.

The fine pattern having concave and convex portions provided on the surface (end face 12a of the mesa portion 12) of the mold 10 preferably has a pattern height of 4 nm (inclusive) to 200 nm (inclusive). As the pattern height is smaller, a force (that is, a mold separation force) to separate the mold 10 from the cured film of the curable composition 30 in a mold separation step (to be described later) becomes lower, decreasing the number of mold separation defects that remain on the mold 10 side owing to damage to the cured film pattern of the curable composition 30 along with mold separation. However, if the pattern height is excessively small, the treatment precision of treatment processing (for example, etching processing) of the substrate 20 performed after imprint processing may become low. To the contrary, if the pattern height is excessively large, the cured film pattern of the curable composition 30 may be elastically deformed by an impact at the time of detaching the mold 10 from the cured film of the curable composition 30. In this case, adjacent convex portions of the cured film pattern may contact each other and the cured film pattern may adhere or be damaged. Therefore, the pattern height of the pattern of the mold 10 having concave and convex portions is desirably double or less of the pattern width (aspect ratio of 2 or less). With this setting, the above-mentioned problems are highly likely to be avoided. As described above, the mold 10 aims to planarize the surface of the curable composition 30 on the substrate 20, and the end face 12a (contact surface) of the mesa portion 12 may be constituted as a flat surface.

The mold 10 may undergo surface treatment before the contact step in order to improve the releasability between the photo-cured curable composition 30 and the surface of the mold 10. As the surface treatment method, a mold separation agent layer is formed by applying a mold separation agent to the surface of the mold 10. Examples of the mold separation agent applied to the surface of the mold 10 are a silicone mold separation agent, a fluorine mold separation agent, a hydrocarbon mold separation agent, a polyethylene mold separation agent, a polypropylene mold separation agent, a paraffin mold separation agent, a montan mold separation agent, and a carnauba mold separation agent. For example, a commercially available coating mold separation agent such as OPTOOL® DSX available from Daikin Chemicals can be preferably used. As the mold separation agent, one type may be used singly, or two or more types may be used together. Of these mold separation agents, a fluorine mold separation agent and a hydrocarbon mold separation agent are especially preferable.

In the contact step, as shown in [2] of FIG. 6, a pressure applied to the mold 10 and/or the curable composition 30 is not particularly limited when bringing the mold 10 and the curable composition 30 into contact with each other. The pressure is set to be 0 MPa (inclusive) to 100 MPa (inclusive). The pressure is preferably 0 MPa (inclusive) to 50 MPa (inclusive), more preferably 0 MPa (inclusive) to 30 MPa (inclusive), and further preferably 0 MPa (inclusive) to 20 MPa (inclusive).

In the contact step, the time over which the mold 10 and the curable composition 30 are kept in contact is not particularly limited and is, for example, 0.1 sec (inclusive) to 600 sec (inclusive). The time is preferably 0.1 sec (inclusive) to 3 sec (inclusive), and more preferably 0.1 sec (inclusive) to 1 sec (inclusive). If the time is shorter than 0.1 sec, spread and fill are insufficient, and many defects called unfilled defects tend to be generated.

The contact step can be performed under any condition such as an air atmosphere, a reduced-pressure atmosphere, or an inert gas atmosphere, and is preferably performed in a reduced-pressure atmosphere and/or an inert gas atmosphere in order to prevent the influence of oxygen or moisture on a curing reaction. The inert gas atmosphere is an atmosphere in which an inert gas is used as an atmosphere control gas. Examples of the inert gas usable when the contact step is performed in the inert gas atmosphere are nitrogen, carbon dioxide, helium, argon, various chlorofluorocarbon gases, and mixed gases thereof. When the contact step is performed in the atmosphere of a specific gas including the air atmosphere, a preferable pressure is 0.0001 atmospheric pressure (inclusive) to 10 atmospheric pressure (inclusive).

### (Curing Step)

Then, a curing step of curing the curable composition 30 in a state in which the mold 10 and the curable composition 30 on the substrate 20 contact each other. In the curing step, as schematically shown in [3] of FIG. 6, the curable composition 30 on the substrate 20 is irradiated with light 63 via the mold 10. More specifically, the curable composition 30 filling the concave portions of the pattern of the mold 10 having concave and convex portions and the gap between the mold 10 and the substrate 20 is irradiated with the light 63 via the mold 10. Accordingly, the curable composition 30 filling the concave portions of the pattern of the mold 10 having concave and convex portions and the gap between the mold 10 and the substrate 20 is cured by the light 63 and changed into a cured film 30′ having a shape in which the pattern of the mold 10 having concave and convex portions is transferred.

The light 63 emitted to the curable composition 30 can be selected in accordance with the sensitivity wavelength of the curable composition 30. More specifically, it is preferable to properly select and use, as the light 63, ultraviolet light having a wavelength of 150 nm (inclusive) to 400 nm (inclusive), an X-ray, an electron beam, or the like. Of these rays, ultraviolet light is especially preferable as the light 63. This is because most of commercially available curing assistants (photopolymerization start agents) are compounds sensitive to ultraviolet light. Examples of a light source that emits ultraviolet light are a high-pressure mercury lamp, an ultra-high-pressure mercury lamp, a low-pressure mercury lamp, a Deep-UV lamp, a carbon-arc lamp, a chemical lamp, a metal halide lamp, a xenon lamp, a KrF excimer laser, an ArF excimer laser, and a F₂ excimer laser. As the light source that emits ultraviolet light, an ultra-high-pressure mercury lamp is especially preferably used. Note that the number of light sources used may be one or more. Light irradiation in the curing step may be performed on the entire curable composition 30 or only on its partial region. The curing step may be performed a plurality of times intermittently on the entire region of the substrate 20 or performed continuously on the entire region of the substrate 20. Further, in the curing step, light irradiation may be performed separately in a plurality of regions of the curable composition 30 on the substrate 20. For example, a partial area A of the curable composition 30 on the substrate 20 may be irradiated with light in the first irradiation step, and a partial area B different from the region A out of the curable composition 30 on the substrate 20 may be irradiated with light in the second irradiation step.

### (Mold Separation Step)

Then, a mold separation step of separating the mold 10 from the cured film 30′ on the substrate 20 is performed. In the mold separation step, as schematically shown in [4] of FIG. 6, the mold 10 is separated (detached) from the cured film 30′ having a shape in which the pattern of the mold 10 having concave and convex portions is transferred. As a result, the cured film 30′ having a pattern shape that is a reverse pattern of the pattern of the mold 10 having concave and convex portions is independently obtained on the substrate 20. Note that the cured film 30′ having the pattern shape includes a residual film 64. The residual film 64 is a film remaining between the substrate 20 and the concave portions of the pattern of the cured film 30′ having concave and convex portions.

When the above-described contact step is performed under a condensable gas atmosphere, the condensable gas vaporizes along with a decrease in the pressure of an interface at which the cured film 30′ and the mold 10 contact each other at the time of separating the cured film 30′ and the mold 10 in the mold separation step. This tends to produce an effect of reducing a mold separation force that is a force necessary to separate the cured film 30′ and the mold 10.

The method of separating the mold 10 and the cured film 30′ having a pattern shape is not particularly limited as long as part of the cured film 30′ having a pattern shape is not physically damaged at the time of separation, and various conditions and the like are also not particularly limited. For example, the cured film 30′ on the substrate 20 and the mold 10 may be separated by fixing the substrate 20 (processing target substrate) and moving the mold 10 apart from the substrate 20. Alternatively, the cured film 30′ on the substrate 20 and the mold 10 may be separated by fixing the mold 10 and moving the substrate 20 apart from the mold 10. Alternatively, the cured film 30′ on the substrate 20 and the mold 10 may be separated by moving both of them in opposite directions (in which they move apart from each other).

Imprint processing including the above-described steps [1] to [4] is executed successively in respective shot regions on the substrate 20. Hence, the cured film 30′ bearing a desired pattern having concave and convex portions (shape in which the pattern of the mold 10 having concave and convex portions is transferred) can be obtained in each shot region (desired position on the substrate).

### <Calculation of Extrusion Height>

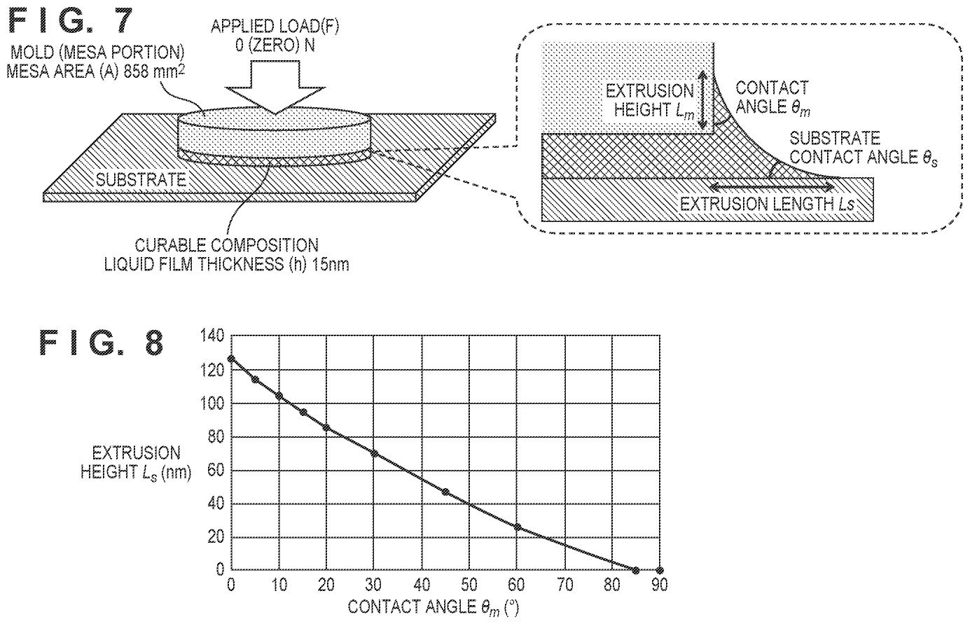

Next, the result of theoretically calculating the relationship between the contact angle (θm) and extrusion height of the curable composition 30 (droplet) on the surface of the liquid repellent layer 13 of the mold 10 will be explained using a model shown in FIG. 7. In this calculation, for simplicity, the mold 10 (mesa portion 12) was approximated as a columnar rigid body having a flat end face 12a (contact surface), the substrate 20 was approximated as a rigid body having a flat surface, and the curable composition 30 was approximated as a Newtonian fluid. The surface (end face 12a of the mesa portion 12) of the mold 10 was a flat surface not bearing a pattern having concave and convex portions. Lubrication approximation was applied to the curable composition 30, the load (F) applied to the mold 10 was 0 N, the mesa area (A) was 858 mm², and the initial liquid film thickness (h) of the curable composition 30 was 15 nm. The mesa area (A) may be understood as the area of the end face 12a of the mesa portion 12 of the mold 10. As physical property values of the curable composition 30, the viscosity (μ) was 5 mPa-s, the surface tension (y) was 30 mN/m, and the substrate contact angle (θs) was 0°. With these settings, the extrusion height (Lm) after 1 sec in a case in which the contact angle (θm) of the curable composition was 0° to 90° on the surface of the liquid repellent layer 13 of the mold 10 was calculated. The extrusion height may be understood as a height to which the curable composition 30 running off from the mesa portion 12 runs up along the side surface 12c of the mesa portion 12 when the mold 10 (mesa portion 12) is pressed against the curable composition 30 on the substrate.

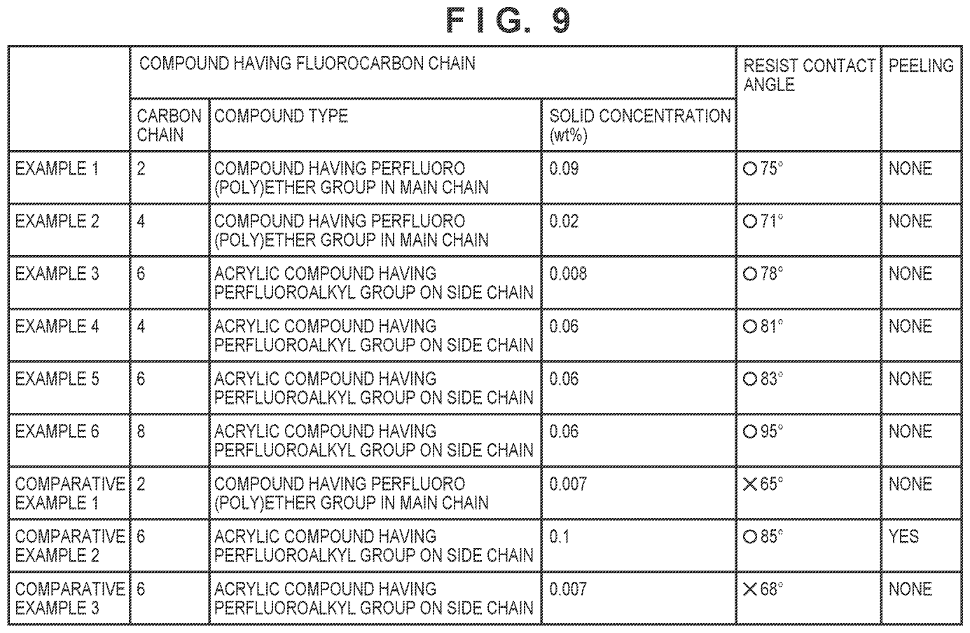

FIG. 8 shows the calculation result. Even if the applied load (F) is 0 N, the mold 10 is pulled and falls to the substrate side by, as a driving force, a meniscus force generated by a meniscus stretched between the mold 10 and the substrate 20, and extrusion occurs owing to a squeeze effect arising from the falling of the mold 10. This behavior was quantitatively calculated. The extrusion height (Lm) was significantly low at a contact angle of 5° or more, about 55% at a contact angle of 30°, about 10% at a contact angle of 70°, and 0 nm at a contact angle of 90°, compared to a case in which the contact angle (θm) on the surface of the liquid repellent layer 13 of the mold 10 was 0°. The calculation shows that extrusion is improved by providing the liquid repellent layer 13 according to the embodiment of the present invention on the mold 10 (side surface 12c of the mesa portion 12).

### <Article Manufacturing Method>

An article manufacturing method according to an embodiment of the present invention is suitable for manufacturing an article, for example, a microdevice such as a semiconductor device or an element having a fine structure. The article manufacturing method according to the embodiment includes a layer forming step of forming a liquid repellent layer on part of a mold using the above-described forming method, and a molding step of molding a curable composition on a substrate using the mold on which the liquid repellent layer is formed. The molding step can include imprint processing of forming a pattern on the curable composition on the substrate using a mold bearing a pattern having concave and convex portions, and/or planarization processing of planarizing the surface of the curable composition on the substrate using a mold having a flat surface. The article manufacturing method according to the embodiment includes a step of processing the substrate having the molded curable composition, and a step of manufacturing an article from the processed substrate. The manufacturing method also includes other known steps (for example, oxidation, deposition, vapor deposition, doping, planarization, etching, resist removal, dicing, bonding, and packaging). The article manufacturing method according to the embodiment is advantageous in at least one of the performance, quality, productivity, and production cost of the article, as compared to conventional methods.

The pattern of a cured product formed using the imprint apparatus is used permanently for at least some of various kinds of articles or temporarily when manufacturing various kinds of articles. The articles are an electric circuit element, an optical element, a MEMS, a recording element, a sensor, a mold, and the like. Examples of the electric circuit element are volatile and nonvolatile semiconductor memories such as a DRAM, an SRAM, a flash memory, and an MRAM and semiconductor elements such as an LSI, a CCD, an image sensor, and an FPGA. Examples of the mold are masks for imprint.

The pattern of the cured product is directly used as the constituent member of at least some of the above-described articles or used temporarily as a resist mask. After etching or ion implantation is performed in the substrate processing step, the resist mask is removed.

### EXAMPLES

To complement the above-described embodiment, more concrete examples for forming a liquid repellent layer 13 on at least part (side surface 12c of a mesa portion 12) of a mold 10 will be explained. FIG. 9 is a view (table) showing Examples 1 to 6 according to the present invention. FIG. 9 also shows Comparative Examples 1 to 3 for comparison with Examples 1 to 6 according to the present invention. In Examples and Comparison Examples, the liquid repellent layer 13 was formed on at least part (side surface 12c of the mesa portion 12) of the mold 10 by the above-described liquid repellent layer forming method. When a curable composition 30 was dropped as a droplet onto the liquid repellent layer 13, acceptance of the contact angle of the droplet (that is, acceptance of liquid repellency) was judged to be O (accepted) at a contact angle of 70° to 100°, and ×(rejected) at a contact angle of less than 70⁰. Measurement of the contact angle used DropMeasure-1000 available from Microjet.

### Example 1

In Example 1, a liquid material prepared by dissolving in a volatile solvent at a solid concentration of 0.09 wt % a compound having in a main chain a perfluoro(poly)ether group whose carbon chain was 2 was used as a liquid repellent material. The contact angle of a droplet of a curable composition 30 dropped onto a liquid repellent layer 13 formed in Example 1 was 750 and accepted. As a result of observing the surface of a mold 10 on which the liquid repellent layer 13 was formed, no peeling occurred in the liquid repellent layer 13 formed on a side surface 12c of a mesa portion 12.

### Example 2

In Example 2, a liquid material prepared by dissolving in a volatile solvent at a solid concentration of 0.02 wt % a compound having in a main chain a perfluoro(poly)ether group whose carbon chain was 4 was used as a liquid repellent material. The contact angle of a droplet of a curable composition 30 dropped onto a liquid repellent layer 13 formed in Example 2 was 710 and accepted. As a result of observing the surface of a mold 10 on which the liquid repellent layer 13 was formed, no peeling occurred in the liquid repellent layer 13 formed on a side surface 12c of a mesa portion 12.

### Example 3

In Example 3, a liquid material prepared by dissolving in a volatile solvent at a solid concentration of 0.008 wt % an acrylic compound having in a side chain a perfluoroalkyl group whose carbon chain was 6 was used as a liquid repellent material. The contact angle of a droplet of a curable composition 30 dropped onto a liquid repellent layer 13 formed in Example 3 was 78° and accepted. As a result of observing the surface of a mold 10 on which the liquid repellent layer 13 was formed, no peeling occurred in the liquid repellent layer 13 formed on a side surface 12c of a mesa portion 12.

### Example 4

In Example 4, a liquid material prepared by dissolving in a volatile solvent at a solid concentration of 0.06 wt % an acrylic compound having in a side chain a perfluoroalkyl group whose carbon chain was 4 was used as a liquid repellent material. The contact angle of a droplet of a curable composition 30 dropped onto a liquid repellent layer 13 formed in Example 4 was 810 and accepted. As a result of observing the surface of a mold 10 on which the liquid repellent layer 13 was formed, no peeling occurred in the liquid repellent layer 13 formed on a side surface 12c of a mesa portion 12.

### Example 5

In Example 5, a liquid material prepared by dissolving in a volatile solvent at a solid concentration of 0.06 wt % an acrylic compound having in a side chain a perfluoroalkyl group whose carbon chain was 6 was used as a liquid repellent material. The contact angle of a droplet of a curable composition 30 dropped onto a liquid repellent layer 13 formed in Example 5 was 830 and accepted. As a result of observing the surface of a mold 10 on which the liquid repellent layer 13 was formed, no peeling occurred in the liquid repellent layer 13 formed on a side surface 12c of a mesa portion 12.

### Example 6

In Example 6, a liquid material prepared by dissolving in a volatile solvent at a solid concentration of 0.06 wt % an acrylic compound having in a side chain a perfluoroalkyl group whose carbon chain was 8 was used as a liquid repellent material. The contact angle of a droplet of a curable composition 30 dropped onto a liquid repellent layer 13 formed in Example 6 was 950 and accepted. As a result of observing the surface of a mold 10 on which the liquid repellent layer 13 was formed, no peeling occurred in the liquid repellent layer 13 formed on a side surface 12c of a mesa portion 12.

### Comparative Example 1

In Comparative Example 1, a liquid material prepared by dissolving in a volatile solvent at a solid concentration of 0.007 wt % a compound having in a main chain a perfluoro(poly)ether group whose carbon chain was 2 was used as a liquid repellent material. The contact angle of a droplet of a curable composition 30 dropped onto a liquid repellent layer 13 formed in Comparative Example 1 was 65° and rejected. As a result of observing the surface of a mold 10 on which the liquid repellent layer 13 was formed, no peeling occurred in the liquid repellent layer 13 formed on a side surface 12c of a mesa portion 12.

### Comparative Example 2

In Comparative Example 2, a liquid material prepared by dissolving in a volatile solvent at a solid concentration of 0.1 wt % an acrylic compound having in a side chain a perfluoroalkyl group whose carbon chain was 6 was used as a liquid repellent material. The contact angle of a droplet of a curable composition 30 dropped onto a liquid repellent layer 13 formed in Comparative Example 2 was 850 and accepted. However, as a result of observing the surface of a mold 10 on which the liquid repellent layer 13 was formed, peeling occurred in the liquid repellent layer 13 formed on a side surface 12c of a mesa portion 12.

### Comparative Example 3

In Comparative Example 3, a liquid material prepared by dissolving in a volatile solvent at a solid concentration of 0.007 wt % an acrylic compound having in a side chain a perfluoroalkyl group whose carbon chain was 6 was used as a liquid repellent material. The contact angle of a droplet of a curable composition 30 dropped onto a liquid repellent layer 13 formed in Comparative Example 3 was 68° and rejected. As a result of observing the surface of a mold 10 on which the liquid repellent layer 13 was formed, no peeling occurred in the liquid repellent layer 13 formed on a side surface 12c of a mesa portion 12.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-015633 filed on Feb. 3, 2023, which is hereby incorporated by reference herein in its entirety.

What is claimed is:

1. A liquid material containing a compound having a fluorocarbon chain and a volatile solvent,
wherein the compound having the fluorocarbon chain is one of a compound having in a main chain a perfluoro(poly)ether group whose carbon number is 2 to 4, and an acrylic compound having in a side chain a perfluoroalkyl group whose carbon number is 4 to 8.

2. The material according to claim 1, wherein a solid concentration of the compound having the fluorocarbon chain with respect to the entire liquid material is 0.008 wt % to 0.09 wt %.

3. The material according to claim 1, wherein a solid concentration of the compound having the fluorocarbon chain with respect to the entire liquid material is 0.01 wt % to 0.09 wt %.

4. The material according to claim 1, wherein a solid concentration of the compound having the fluorocarbon chain with respect to the entire liquid material is 0.02 wt % to 0.07 wt %.

5. A mold that includes a base body having a major surface and a convex portion projecting from the major surface, and presses an end face of the convex portion against a liquid curable composition on a substrate to mold the curable composition,
wherein a liquid repellent layer having liquid repellency with respect to the curable composition is provided on at least part of a side surface of the convex portion, and
the liquid repellent layer contains one of a compound having in a main chain a perfluoro(poly)ether group whose carbon number is 2 to 4, and an acrylic compound having in a side chain a perfluoroalkyl group whose carbon number is 4 to 8.

6. The mold according to claim 5, wherein the liquid repellent layer has a characteristic in which when the curable composition is dropped as a droplet onto the liquid repellent layer, a contact angle of the droplet is not less than 70° to less than 100°.

7. A method of forming a liquid repellent layer having liquid repellency with respect to a liquid curable composition on part of a mold, wherein the mold includes a base body having a major surface and a convex portion projecting from the major surface, and the mold includes an end face of the convex portion as a surface pressed against the curable composition on a substrate, the method comprising:
supplying a liquid material defined in claim 1 to at least part of a side surface of the convex portion; and
volatilizing a volatile solvent contained in the liquid material after the supplying.

8. An article manufacturing method comprising:
forming a liquid repellent layer on part of a mold by a forming method defined in claim 7;
molding a curable composition on a substrate using the mold on which the liquid repellent layer is formed;
processing the substrate including the molded curable composition; and
manufacturing an article from the processed substrate.

9. A forming apparatus that forms a liquid repellent layer having liquid repellency with respect to a liquid curable composition on part of a mold, wherein the mold includes a base body having a major surface and a convex portion projecting from the major surface, and the mold includes an end face of the convex portion as a surface pressed against the curable composition on a substrate, the apparatus comprising:
a stage configured to hold the mold;
a supply head configured to supply a liquid material defined in claim 1 to at least part of a side surface of the convex portion; and
a controller configured to control processing of supplying the liquid material to part of the mold while relatively moving the stage and the supply head.

10. An imprint apparatus that forms a pattern of a curable composition on a substrate using a mold, wherein the mold includes a base body having a major surface and a convex portion projecting from the major surface, and the mold includes, on an end face of the convex portion, a pattern having concave and convex portions that is transferred to the curable composition on the substrate, the apparatus comprising:
a forming apparatus defined in claim 9 that forms, on part of the mold, a liquid repellent layer having liquid repellency with respect to the curable composition.

11. A planarization apparatus that planarizes a curable composition on a substrate using a mold, wherein the mold includes a base body having a major surface and a convex portion projecting from the major surface, and an end face of the convex portion is constituted as a flat surface for planarizing the curable composition on the substrate, the apparatus comprising:
a forming apparatus defined in claim 9 that forms, on part of the mold, a liquid repellent layer having liquid repellency with respect to the curable composition.
